(19) United States
(12) Patent Application Publication
(10) Pub. No.: US 2019/0354211 A1
(43) Pub. Date: Nov. 21, 2019

(54) TOUCH PANEL AND TOUCH DISPLAY DEVICE

(71) Applicant: Wuhan China Star Optoelectronics Semiconductor Display Technology Co., Ltd., Wuhan (CN)

(72) Inventor: Bo LI, Wuhan (CN)

(21) Appl. No.: 16/203,245

(22) Filed: Nov. 28, 2018

Related U.S. Application Data
(63) Continuation of application No. PCT/CN2018/097105, filed on Jul. 25, 2018.

(30) Foreign Application Priority Data
May 15, 2018 (CN) 201810460282.1

(51) Int. Cl. G06F 3/044; H03K 17/96; G06F 3/041

(52) U.S. Cl. CPC G06F 3/044; H03K 17/962; G06F 3/0412; G06F 2203/04111; G06F 2203/04107; G06F 2203/04102; H03K 2017/9613

(57) ABSTRACT

Disclosed is a touch panel, comprising a substrate, wherein a touch function area, a metal trace area, and a pressed leading out area are formed on the substrate; the touch function area comprises sensing electrode chains and driving electrode chains arranged at intervals; the sensing electrode chain comprises sensing electrodes made of a first conductive metal, and the adjacent two sensing electrodes are bridged by at least one connecting bridge; each connecting bridge is provided with two through holes, and an electrical conduction between the two bridged sensing electrodes is achieved by a first conductive metal oxide film layer covering an upper surface of the connecting bridge and extending into the two through holes; the driving electrode comprises driving electrodes made of a second conductive metal and connected in series; each driving electrode in the driving electrode chains and each sensing electrode in the sensing electrode chains are insulated.

### CROSS-REFERENCE TO RELATED APPLICATION

This application is a continuing application of PCT Patent Application No. PCT/CN2018/097105 entitled “Touch panel and touch display device”, filed on Jul. 25, 2018, which claims priority to Chinese Patent Application No. 201810460282.1, filed on May 15, 2018, both of which are hereby incorporated in its entireties by reference.

### FIELD OF THE INVENTION

The present invention relates to a touch screen field, and more particularly to a touch panel and a touch display device.

### BACKGROUND OF THE INVENTION

With the rapid development of Active Matrix Organic Light Emitting Diode (AMOLED) screen technology, flexible foldable displays have become reality, and fixed-curve surface products have already been introduced to the market.

However, unlike the singularity of display technology, touch technology is relatively simple and has significant diversity. At present, the most commonly used material for touch technology is indium tin oxide (ITO). ITO may have types of on glass solution (OGS) touch and external film touch, On-Cell touch and In-Cell for LCD screen according to the material and the applied position. In addition, the materials used in touch technology include metal-mesh for large-size touch, and some relatively immature alternative technologies, such as nano-silver materials, graphene materials and conductive polymer materials. Despite the emergence of alternative technologies, ITO has dominated the market with its good optical properties and mature production processes, and has become more stable under the current trend of high definition display.

Because of the fragile nature of ITO due to the material itself, in the case where the bent radius of curvature is smaller, there is a risk that the ITO is broken and the function is disabled. Therefore, under the current development trend of fixed-curve surface and foldable product, there is an urgent need to reduce the risk of ITO fracture, and to develop a more flexible material to replace ITO and to improve the quality of the touch panel.

### SUMMARY OF THE INVENTION

An objective of the present invention is to provide a touch panel and a touch display device, to reduce the risk of ITO fracture and to utilize a more flexible composite material to replace ITO for improving the quality of production.

For solving the aforesaid technical issues, the embodiment of the present invention provides a touch panel, comprising a substrate, wherein a touch function area, a metal trace area, and a pressed leading out area are respectively formed on the substrate; wherein

the touch function area comprises a plurality of sensing electrode chains arranged at intervals and a plurality of driving electrode chains arranged at intervals; wherein

each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;

each of the driving electrode chains comprises a plurality of driving electrodes, made of a second conductive metal and connected in series; each of the driving electrodes in each of the driving electrode chains and each of sensing electrodes in each of the sensing electrode chains are insulated.

The first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

The metal trace area is provided with a plurality of first connecting electrodes, correspondingly connected to all of the sensing electrode chains and the driving electrode chains in the touch function area; wherein

the first connecting electrode is a single layer structure formed by a second conductive metal oxide; or a composite metal structure formed by at least the second conductive metal oxide and a third conductive metal.

The first connecting electrode of the composite metal structure comprises a bottom layer made of one of metal silver, metal copper and metal aluminum as the third conductive metal, and a top layer made of one of ITO, IGZO and IZO as the second conductive metal oxide; or

the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

The pressed leading out area is provided with a plurality of second connecting electrodes respectively connected to all of the first connecting electrodes of the metal trace area by metal traces; wherein

the second connecting electrode is a single layer structure formed by a third conductive metal oxide; or a composite metal structure formed by at least the third conductive metal oxide and a fourth conductive metal.

The second connecting electrode of the composite metal structure comprises a bottom layer made of one of metal silver, metal copper and metal aluminum as the fourth conductive metal, and a top layer made of one of ITO, IGZO and IZO as the third conductive metal oxide; or

the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.

The inorganic insulating material comprises silicon oxide, silicon nitride, and silicon dioxide; the organic insulating material comprises acryl, polyurethane, and polysiloxane; and the substrate is made of cyclic olefin copolymer or ethylene terephthalate.

The touch panel further comprises an insulating protective layer for blocking intrusion of water oxygen in air; wherein the insulating protective layer covers the metal trace area and the touch function area.

The insulating protective layer further covers a partial area above the second connecting electrode of the pressed leading out area.

Correspondingly, the embodiment of the present invention further provides a touch panel, comprising a substrate, wherein a touch function area, a metal trace area, and a pressed leading out area are respectively formed on the substrate; wherein

the touch function area comprises a plurality of sensing electrode chains arranged at intervals and a plurality of driving electrode chains arranged at intervals; wherein

each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;

each of the driving electrode chains comprises a plurality of driving electrodes, made of a second conductive metal and connected in series; each of the driving electrodes in each of the driving electrode chains and each of sensing electrodes in each of the sensing electrode chains are insulated;

The metal trace area is provided with a plurality of first connecting electrodes, correspondingly connected to all of the sensing electrode chains and the driving electrode chains in the touch function area; wherein

the first connecting electrode is a single layer structure formed by a second conductive metal oxide; or a composite metal structure formed by at least the second conductive metal oxide and a third conductive metal;

The pressed leading out area is provided with a plurality of second connecting electrodes respectively connected to all of the first connecting electrodes of the metal trace area by metal traces; wherein

the second connecting electrode is a single layer structure formed by a third conductive metal oxide; or a composite metal structure formed by at least the third conductive metal oxide and a fourth conductive metal.

The first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

The first connecting electrode of the composite metal structure comprises a bottom layer made of one of metal silver, metal copper and metal aluminum as the third conductive metal, and a top layer made of one of ITO, IGZO and IZO as the second conductive metal oxide; or

the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

The second connecting electrode of the composite metal structure comprises a bottom layer made of one of metal silver, metal copper and metal aluminum as the fourth conductive metal, and a top layer made of one of ITO, IGZO and IZO as the third conductive metal oxide; or

the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.

The touch panel further comprises an insulating protective layer for blocking intrusion of water oxygen in air; wherein the insulating protective layer covers the metal trace area and the touch function area, and the insulating protective layer further covers a partial area above the second connecting electrode of the pressed leading out area.

Correspondingly, the embodiment of the present invention further provides a touch display device, comprising a touch panel, wherein the touch panel comprises a substrate, wherein a touch function area, a metal trace area, and a pressed leading out area are respectively formed on the substrate; wherein

the touch function area comprises a plurality of sensing electrode chains arranged at intervals and a plurality of driving electrode chains arranged at intervals; wherein

each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;

each of the driving electrode chains comprises a plurality of driving electrodes, made of a second conductive metal and connected in series; each of the driving electrodes in each of the driving electrode chains and each of sensing electrodes in each of the sensing electrode chains are insulated.

The first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

The metal trace area is provided with a plurality of first connecting electrodes, correspondingly connected to all of the sensing electrode chains and the driving electrode chains in the touch function area; wherein

the first connecting electrode is a single layer structure formed by a second conductive metal oxide; or a composite metal structure formed by at least the second conductive metal oxide and a third conductive metal.

The first connecting electrode of the composite metal structure comprises a bottom layer made of one of metal silver, metal copper and metal aluminum as the third conductive metal, and a top layer made of one of ITO, IGZO and IZO as the second conductive metal oxide; or

the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

The pressed leading out area is provided with a plurality of second connecting electrodes respectively connected to all of the first connecting electrodes of the metal trace area by metal traces; wherein

the second connecting electrode is a single layer structure formed by a third conductive metal oxide; or a composite metal structure formed by at least the third conductive metal oxide and a fourth conductive metal.

The second connecting electrode of the composite metal structure comprises a bottom layer made of one of metal silver, metal copper and metal aluminum as the fourth conductive metal, and a top layer made of one of ITO, IGZO and IZO as the third conductive metal oxide; or

the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.

In conclusion, with implementing the embodiments of the present invention, the benefits are:

1, compared with the conventional touch panel, the present invention uses the first conductive metal and the second conductive metal instead of the conventional ITO to respectively form the sensing electrode and the driving electrode of the touch function area in the touch panel, so that in the touch panel, the electrode material on the touch function area is a more flexible composite material (such as conductive metal+conductive metal oxide), which not only ensures good electrical conductivity, but also avoids the risk of easy breakage caused by the traditional use of ITO materials alone to further improve the quality of production;

2. compared with the conventional touch panel, the present invention also arranges the first connecting electrode of the metal trace area in the touch panel to replace the traditional ITO by the composite metal structure of the third conductive metal and the second conductive metal oxide, which not only improves the flexibility of the electrode material on the metal trace area, but also ensures good electrical conductivity, and avoids the risk of easy breakage caused by the traditional use of ITO materials alone to further improve the production quality;

3. compared with the conventional touch panel, the present invention also arranges the second connecting electrode of the touch panel in the pressed leading out area to replace the conventional ITO by the composite metal structure of the fourth conductive metal and the third conductive metal oxide, which not only improves the flexibility of the electrode material on the pressed leading out area, but also ensures good electrical conductivity, and avoids the risk of easy breakage caused by the traditional use of ITO materials alone to further improve the production quality.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a top view planar diagram of a touch panel according to an embodiment of the present invention;

FIG. 2 is a sectional diagram along line D-D of FIG. 1;

FIG. 3 is another sectional diagram along line D-D of FIG. 1;

FIG. 4 is one another sectional diagram along line D-D of FIG. 1;

FIG. 5 is a sectional diagram along line D-D of FIG. 1;

FIG. 6 is another sectional diagram along line D-D of FIG. 1;

FIG. 7 is one another sectional diagram along line D-D of FIG. 1.

### DETAILED DESCRIPTION OF PREFERRED EMBODIMENTS

In order to make the objectives, technical solutions, and advantages of the embodiments of the disclosure more apparent, the present invention will be described below in detail with reference to the drawings.

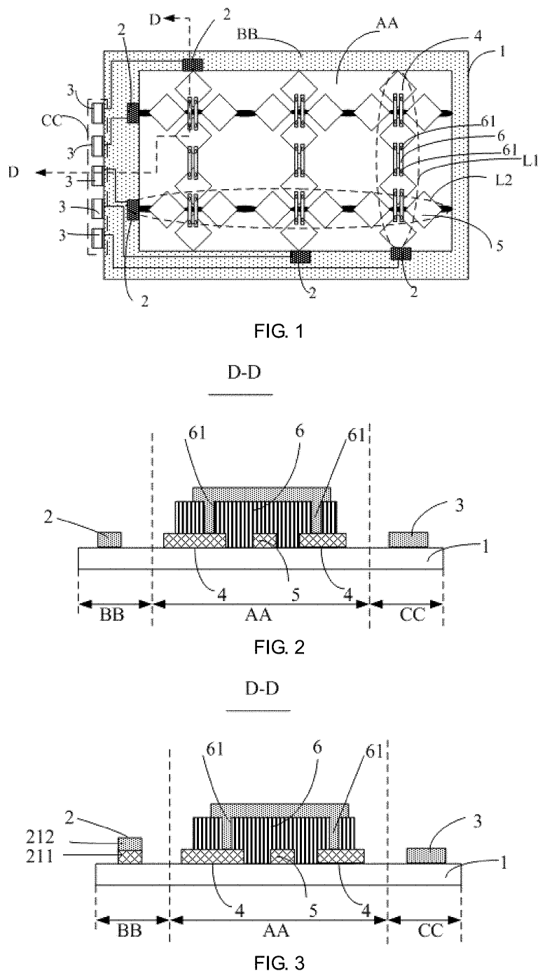

As shown in FIGS. 1 to 7, which is the first embodiment of the present invention, provided is a touch panel, comprising a substrate 1 made of a cyclic olefin copolymer (COP) or a polyethylene terephthalate (PET), so that the touch panel can be a flexible panel possessing flodability; wherein

The substrate 1 is respectively formed with a touch function area AA for integrating the corresponding touch electrodes, a metal trace area BB for the metal traces, and a pressed leading out area CC for bonding to the external components. The metal trace area BB located at the periphery of the touch function area AA connects all of the sensing electrode chains and driving electrode chains in the touch function area AA to the pressed leading out area CC through the metal traces, so that the sensing electrode chains and the driving electrode chains in the touch function area AA can obtain corresponding phase control signals provided by the external components bound in the pressed leading out area CC;

wherein the touch function area AA comprises a plurality of sensing electrode chains L1 arranged at intervals and a plurality of driving electrode chains L2 arranged at intervals;

each of the sensing electrode chains L1 comprises a plurality of sensing electrodes 4 made of a first conductive metal, and the adjacent two sensing electrodes 4 are bridged by at least one connecting bridge 6; each connecting bridge 6 in each of the sensing electrode chains L1 is provided with two through holes 61 at two ends of the connecting bridge, and an electrical conduction between the two bridged sensing electrodes 4 is achieved by a first conductive metal oxide film layer covering an upper surface of the connecting bridge and extending into the two through holes 61; wherein the connecting bridge 6 is made of an inorganic insulating material or an organic insulating material;

each of the driving electrode chains L2 comprises a plurality of driving electrodes 5 made of a second conductive metal, and the plurality of driving electrodes 5 is connected in series; each of the driving electrodes 5 in each of the driving electrode chains L2 and each of sensing electrodes 4 in each of the sensing electrode chains L1 are insulated;

wherein the metal trace area BB is provided with a plurality of first connecting electrodes 2, correspondingly connected to all of the sensing electrode chains and the driving electrode chains in the touch function area AA; the first connecting electrode 2 is a single layer structure formed by a second conductive metal oxide; or a composite metal structure formed by at least the second conductive metal oxide and a third conductive metal;

wherein the pressed leading out area CC is provided with a plurality of second connecting electrodes 3 respectively connected to all of the first connecting electrodes 2 of the metal trace area BB by metal traces; the second connecting electrode 3 is a single layer structure formed by a third conductive metal oxide; or a composite metal structure formed by at least the third conductive metal oxide and a fourth conductive metal.

Certainly, for blocking intrusion of water oxygen in air, the touch panel further comprises an insulating protective layer 7 thereabove. The insulating protective layer 7 covers the metal trace area BB and the touch function area AA. Meanwhile, for protecting the second connecting electrode 3 of the pressed leading out area CC, the insulating protective layer 7 further covers a partial area above the second connecting electrode 3 of the pressed leading out area CC, thereby, not interfering with the bonding connection with external components and ensuring the bonding result.

Specifically, considering the fragility of ITO, each of the sensing electrodes 4 in each of the sensing electrode chains L1 and each of the driving electrodes 5 on each of the driving electrode chains L2 in the touch function area AA are made of a conductive metal. The adjacent two sensing electrodes 4 in each of the sensing electrode chains L1 are electrically connected by the first conductive metal oxide. Therefore, the electrode material on the touch function area of the touch panel is formed by a more flexible composite material of conductive metal+conductive metal oxide, which not only ensures good electrical conductivity, but also avoids the risk of easy breakage caused by the traditional use of ITO materials alone to further improve the quality of production. Certainly, in the case of sufficient budget, the electrode materials of the first connecting electrode 2 of the metal trace area BB and/or the second connecting electrode 3 of the pressed leading out area CC both adopt the composite material of conductive metal+conductive metal oxide to replace traditional ITO material. In case of ensuring good electrical conductivity, the risk of easy breakage caused by the traditional use of ITO materials alone can be avoided to further improve the quality of production.

Specifically, the first connecting electrode 2 of the metal trace area BB adopts a composite metal structure, and may be a structure in which the third conductive metal is at the bottom and the second conductive metal oxide is at the top, or may be a structure in which the second conductive metal oxide at the bottom and the third conductive metal is at the top. Once the composite metal structure of the first connecting electrode 2 adopts the structure in which the top is the third conductive metal, since the third conductive metal is exposed on the top and is easily oxidized, the conductive effect is weakened or lost, so that a first anti-oxidation layer is further disposed on the third conductive metal of the composite metal structure. The first anti-oxidation layer may be an insulating layer formed by an inorganic insulating material or an organic insulating material, or may be a conductive film layer formed by, but not limited to, one of ITO, IGZO and IZO.

Similarly, the second connecting electrode 3 of the pressed leading out area CC adopts the composite metal structure, and may be the structure in which the fourth conductive metal is at the bottom and the third conductive metal oxide is at the top, and may be the structure in which the third conductive metal oxide is at the bottom and the fourth conductive metal is at the top. Once the composite metal structure of the second connecting electrode 3 adopts the structure in which the top is the fourth conductive metal, since the fourth conductive metal is exposed on the top and is easily oxidized, the conductive effect is weakened or lost, so that a second anti-oxidation layer is further disposed on the fourth conductive metal of the composite metal structure. Considering that the second connecting electrode 3 of the pressed leading out area CC has to be bonded with the external components and must have good conductivity, the second anti-oxidation layer only includes a conductive film layer formed by, but not limited to one of ITO, IGZO and IZO.

In the first embodiment of the present invention, the first conductive metal, the second conductive metal, the third conductive metal and the fourth conductive metal all include, but not limited to, metallic silver, metallic copper and metallic aluminum; the first conductive metal oxide, the second conductive metal oxide and the third conductive metal oxide all include, but not limited to, one of indium tin oxide (ITO), indium gallium zinc oxide (IGZO) and indium zinc oxide (IZO); the inorganic insulating materials include, but are not limited to, silicon oxide, silicon nitride and silicon dioxide; the organic insulating materials include, but are not limited to, acrylic, polyurethane and polysiloxane.

Referring to FIG. 2 to FIG. 7, the electrode structures corresponding to the touch function area, the metal trace area and the pressed leading out area formed in the touch panel according to the first embodiment of the present invention can be further illustrated as follows:

In one embodiment, as shown in FIG. 2, each of the sensing electrodes 4 in each of the sensing electrode chains and each of the driving electrodes 5 in each of the driving electrode chains in the touch function area AA are made of metal silver (Ag). The electrical conduction between the adjacent two sensing electrodes 4 is achieved by the ITO conductive film layer;

then, the first connecting electrode 2 of the metal trace area BB and the second connecting electrode 3 of the pressed leading out area CC are still fabricated by using ITO of the conventional single layer structure.

In another embodiment, as shown in FIG. 3, each of the sensing electrodes 4 in each of the sensing electrode chains and each of the driving electrodes 5 in each of the driving electrode chains in the touch function area AA are made of metal silver (Ag). The electrical conduction between the adjacent two sensing electrodes 4 is achieved by the ITO conductive film layer;

then, the first connecting electrode 2 of the metal trace area BB adopts the composite metal structure, and the metal silver (Ag) is used as the third conductive metal to form the bottom layer 211, and the ITO is used as the second conductive metal oxide to form the conductive film layer as the top layer 212 over the third conductive metal (Ag);

then, the second connecting electrode 3 of the pressed leading out area CC are still fabricated by using ITO of the conventional single layer structure.

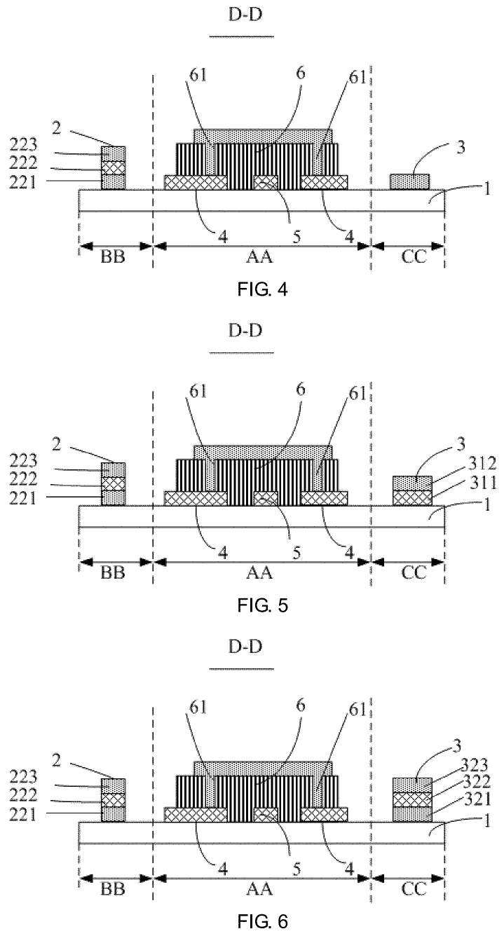

In one another embodiment, as shown in FIG. 4, each of the sensing electrodes 4 in each of the sensing electrode chains and each of the driving electrodes 5 in each of the driving electrode chains in the touch function area AA are made of metal silver (Ag). The electrical conduction between the adjacent two sensing electrodes 4 is achieved by the ITO conductive film layer;

then, the first connecting electrode 2 of the metal trace area BB adopts the composite metal structure, and the ITO is used as the second conductive metal oxide to form the conductive film layer as the bottom layer 221, and the metal silver (Ag) is used as the third conductive metal to form the middle layer 222 on the bottom layer 221 formed by the ITO, and still, the ITO is used to form the conductive film layer as the top layer 223 (i.e. the first anti-oxidation layer) on the middle layer 222 formed by the third conductive metal (Ag); certainly, the inorganic insulating material or the organic insulating material can be used to form the insulating layer as the top layer 223;

then, the second connecting electrode 3 of the pressed leading out area CC are still fabricated by using ITO of the conventional single layer structure.

In one another embodiment, as shown in FIG. 5, each of the sensing electrodes 4 in each of the sensing electrode chains and each of the driving electrodes 5 in each of the driving electrode chains in the touch function area AA are made of metal silver (Ag). The electrical conduction between the adjacent two sensing electrodes 4 is achieved by the ITO conductive film layer;

then, the first connecting electrode 2 of the metal trace area BB adopts the composite metal structure, and the ITO is used as the second conductive metal oxide to form the conductive film layer as the bottom layer 221, and the metal silver (Ag) is used as the third conductive metal to form the middle layer 222 on the bottom layer 221 formed by the ITO, and still, the ITO is used to form the conductive film layer as the top layer 223 (i.e. the first anti-oxidation layer) on the middle layer 222 formed by the third conductive metal (Ag); certainly, the inorganic insulating material or the organic insulating material can be used to form the insulating layer as the top layer 223;

the second connecting electrode 3 of the pressed leading out area CC adopts the composite metal structure, and the metal silver (Ag) is used as the fourth conductive metal to form the bottom layer 311, and the ITO is used as the third conductive metal oxide to form the conductive film layer as the top layer 312 on the third conductive metal (Ag).

In one another embodiment, as shown in FIG. 6, each of the sensing electrodes 4 in each of the sensing electrode chains and each of the driving electrodes 5 in each of the driving electrode chains in the touch function area AA are made of metal silver (Ag). The electrical conduction between the adjacent two sensing electrodes 4 is achieved by the ITO conductive film layer;

then, the first connecting electrode 2 of the metal trace area BB adopts the composite metal structure, and the ITO is used as the second conductive metal oxide to form the conductive film layer as the bottom layer 221, and the metal silver (Ag) is used as the third conductive metal to form the middle layer 222 on the bottom layer 221 formed by the ITO, and still, the ITO is used to form the conductive film layer as the top layer 223 (i.e. the first anti-oxidation layer) on the middle layer 222 formed by the third conductive metal (Ag); certainly, the inorganic insulating material or the organic insulating material can be used to form the insulating layer as the top layer 223;

the second connecting electrode 3 of the pressed leading out area CC adopts the composite metal structure, and the ITO is used as the third conductive metal oxide to form the conductive film layer as the bottom layer 321, and the metal silver (Ag) is used as the fourth conductive metal to form the middle layer 222 on the bottom layer 321 formed by the ITO, and still, the ITO is used to form the conductive film layer as the top layer 323 (i.e. the second anti-oxidation layer) on the middle layer 322 formed by the third conductive metal (Ag).

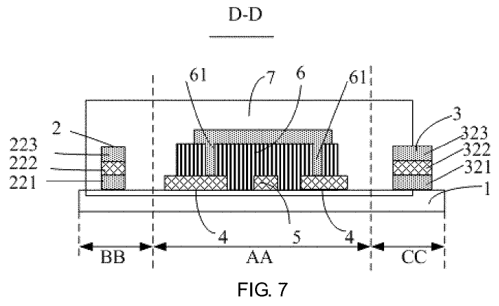

In another embodiment, as shown in FIG. 7, the difference of the technical solution of FIG. 7 from the technical solution of FIG. 6 is that, based on the technical solution of FIG. 6, the insulating protective layer 7 covers the touch function area AA, the metal trace area BB and a partial area above the second connecting electrode 3 of the pressed leading out area CC.

Corresponding to the touch panel provided by the first embodiment of the present invention, the second embodiment of the present invention further provides a touch display device, which includes the touch panel provided by the first embodiment of the present invention. The touch panel of the second embodiment of the present invention has the same structure and connection relationships as the touch panel of the first embodiment of the present invention. For details, refer to the related content of the touch panel in the first embodiment of the present invention. The details are not described herein again.

In conclusion, the implementation of the embodiments of the present invention possesses the benefits:

1, compared with the conventional touch panel, the present invention uses the first conductive metal and the second conductive metal instead of the conventional ITO to respectively form the sensing electrode and the driving electrode of the touch function area in the touch panel, so that in the touch panel, the electrode material on the touch function area is a more flexible composite material (such as conductive metal+conductive metal oxide), which not only ensures good electrical conductivity, but also avoids the risk of easy breakage caused by the traditional use of ITO materials alone to further improve the quality of production;

2. compared with the conventional touch panel, the present invention also arranges the first connecting electrode of the metal trace area in the touch panel to replace the traditional ITO by the composite metal structure of the third conductive metal and the second conductive metal oxide, which not only improves the flexibility of the electrode material on the metal trace area, but also ensures good electrical conductivity, and avoids the risk of easy breakage caused by the traditional use of ITO materials alone to further improve the production quality;

3. compared with the conventional touch panel, the present invention also arranges the second connecting electrode of the touch panel in the pressed leading out area to replace the conventional ITO by the composite metal structure of the fourth conductive metal and the third conductive metal oxide, which not only improves the flexibility of the electrode material on the pressed leading out area, but also ensures good electrical conductivity, and avoids the risk of easy breakage caused by the traditional use of ITO materials alone to further improve the production quality.

The above content with the specific preferred embodiments of the present invention is further made to the detailed description, the specific embodiments of the present invention should not be considered limited to these descriptions. Those of ordinary skill in the art for the present invention, without departing from the spirit of the present invention, can make various simple deduction or replacement, should be deemed to belong to the scope of the present invention.

What is claimed is:

1. A touch panel, comprising a substrate, wherein a touch function area, a metal trace area, and a pressed leading out area are respectively formed on the substrate; wherein
the touch function area comprises a plurality of sensing electrode chains arranged at intervals and a plurality of driving electrode chains arranged at intervals; wherein
each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;
each of the driving electrode chains comprises a plurality of driving electrodes, made of a second conductive metal and connected in series; each of the driving electrodes in each of the driving electrode chains and each of sensing electrodes in each of the sensing electrode chains are insulated.

2. The touch panel according to claim 1, wherein the first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

3. The touch panel according to claim 2, wherein the metal trace area is provided with a plurality of first connecting electrodes, correspondingly connected to all of the sensing electrode chains and the driving electrode chains in the touch function area; wherein
the first connecting electrode is a single layer structure formed by a second conductive metal oxide; or a composite metal structure formed by at least the second conductive metal oxide and a third conductive metal.

4. The touch panel according to claim 3, wherein the first connecting electrode of the composite metal structure comprises a bottom layer made of one of metal silver, metal copper and metal aluminum as the third conductive metal, and a top layer made of one of ITO, IGZO and IZO as the second conductive metal oxide; or
the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

5. The touch panel according to claim 4, wherein the pressed leading out area is provided with a plurality of second connecting electrodes respectively connected to all of the first connecting electrodes of the metal trace area by metal traces;
wherein the second connecting electrode is a single layer structure formed by a third conductive metal oxide; or a composite metal structure formed by at least the third conductive metal oxide and a fourth conductive metal.

6. The touch panel according to claim 5, wherein the second connecting electrode of the composite metal structure comprises a bottom layer made of one of metal silver, metal copper and metal aluminum as the fourth conductive metal, and a top layer made of one of ITO, IGZO and IZO as the third conductive metal oxide; or
the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.

7. The touch panel according to claim 6, wherein the inorganic insulating material comprises silicon oxide, silicon nitride, and silicon dioxide; the organic insulating material comprises acryl, polyurethane, and polysiloxane; and the substrate is made of cyclic olefin copolymer or ethylene terephthalate.

8. The touch panel according to claim 7, further comprising an insulating protective layer for blocking intrusion of water oxygen in air; wherein the insulating protective layer covers the metal trace area and the touch function area.

9. The touch panel according to claim 8, wherein the insulating protective layer further covers a partial area above the second connecting electrode of the pressed leading out area.

10. A touch panel, comprising a substrate, wherein a touch function area, a metal trace area, and a pressed leading out area are respectively formed on the substrate; wherein
the touch function area comprises a plurality of sensing electrode chains arranged at intervals and a plurality of driving electrode chains arranged at intervals; wherein
each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;
each of the driving electrode chains comprises a plurality of driving electrodes, made of a second conductive metal and connected in series; each of the driving electrodes in each of the driving electrode chains and each of sensing electrodes in each of the sensing electrode chains are insulated;
the metal trace area is provided with a plurality of first connecting electrodes, correspondingly connected to all of the sensing electrode chains and the driving electrode chains in the touch function area; wherein
the first connecting electrode is a single layer structure formed by a second conductive metal oxide; or a composite metal structure formed by at least the second conductive metal oxide and a third conductive metal;
the pressed leading out area is provided with a plurality of second connecting electrodes respectively connected to all of the first connecting electrodes of the metal trace area by metal traces; wherein
the second connecting electrode is a single layer structure formed by a third conductive metal oxide; or a composite metal structure formed by at least the third conductive metal oxide and a fourth conductive metal.

11. The touch panel according to claim 10, wherein the first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

12. The touch panel according to claim 11, wherein the first connecting electrode of the composite metal structure comprises a bottom layer made of one of metal silver, metal copper and metal aluminum as the third conductive metal, and a top layer made of one of ITO, IGZO and IZO as the second conductive metal oxide; or
the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

13. The touch panel according to claim 12, wherein the second connecting electrode of the composite metal structure comprises a bottom layer made of one of metal silver, metal copper and metal aluminum as the fourth conductive metal, and a top layer made of one of ITO, IGZO and IZO as the third conductive metal oxide; or
the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.

14. The touch panel according to claim 13, further comprising an insulating protective layer for blocking intrusion of water oxygen in air; wherein the insulating protective layer covers the metal trace area and the touch function area, and the insulating protective layer further covers a partial area above the second connecting electrode of the pressed leading out area.

15. A touch display device, comprising a touch panel, wherein the touch panel comprises a substrate, wherein a touch function area, a metal trace area, and a pressed leading out area are respectively formed on the substrate; wherein
the touch function area comprises a plurality of sensing electrode chains arranged at intervals and a plurality of driving electrode chains arranged at intervals; wherein
each of the sensing electrode chains comprises a plurality of sensing electrodes made of a first conductive metal, and the adjacent two sensing electrodes are bridged by at least one connecting bridge; each connecting bridge in each of the sensing electrode chains is provided with two through holes at two ends of the connecting bridge, and an electrical conduction between the two bridged sensing electrodes is achieved by a first conductive metal oxide film layer covering an upper surface of the connecting bridge and extending into the two through holes;
each of the driving electrode chains comprises a plurality of driving electrodes, made of a second conductive metal and connected in series; each of the driving electrodes in each of the driving electrode chains and each of sensing electrodes in each of the sensing electrode chains are insulated.

16. The touch display device according to claim 15, wherein the first conductive metal is one of metal silver, metal copper and metal aluminum; the second conductive metal comprises one of metal silver, metal copper and metal aluminum; the first conductive metal oxide film layer is formed by one of ITO, IGZO and IZO; the connecting bridge is made of an inorganic insulating material or an organic insulating material.

17. The touch display device according to claim 16, wherein the metal trace area is provided with a plurality of first connecting electrodes, correspondingly connected to all of the sensing electrode chains and the driving electrode chains in the touch function area; wherein
the first connecting electrode is a single layer structure formed by a second conductive metal oxide; or a composite metal structure formed by at least the second conductive metal oxide and a third conductive metal.

18. The touch display device according to claim 17, wherein the first connecting electrode of the composite metal structure comprises a bottom layer made of one of metal silver, metal copper and metal aluminum as the third conductive metal, and a top layer made of one of ITO, IGZO and IZO as the second conductive metal oxide; or
the first connecting electrode of the composite metal structure comprises a bottom layer made of one of ITO, IGZO and IZO as the second conductive metal oxide, a middle layer made of one of metal silver, metal copper and metal aluminum as the third conductive metal which is disposed on the bottom layer made of one of ITO, IGZO and IZO, and a first anti-oxidation layer which is disposed on the middle layer made of one of metal silver, metal copper and metal aluminum; wherein the first anti-oxidation layer is an insulating layer made of an inorganic insulating material or an organic insulating material, or a conductive film layer made of at least one of ITO, IGZO and IZO.

19. The touch display device according to claim 18, wherein the pressed leading out area is provided with a plurality of second connecting electrodes respectively connected to all of the first connecting electrodes of the metal trace area by metal traces; wherein
the second connecting electrode is a single layer structure formed by a third conductive metal oxide; or a composite metal structure formed by at least the third conductive metal oxide and a fourth conductive metal.

20. The touch display device according to claim 19, wherein the second connecting electrode of the composite metal structure comprises a bottom layer made of one of metal silver, metal copper and metal aluminum as the fourth conductive metal, and a top layer made of one of ITO, IGZO and IZO as the third conductive metal oxide; or
the second connecting electrode of the composite metal structure comprises a bottom layer made of one of ITO, IGZO and IZO as the third conductive metal oxide, a middle layer made of one of metal silver, metal copper and metal aluminum as the fourth conductive metal which is disposed on the bottom layer made of one of ITO, IGZO and IZO, and a second anti-oxidation layer which is disposed on the middle layer made of one of metal silver, metal copper and metal aluminum; wherein the second anti-oxidation layer is a conductive film layer made of at least one of ITO, IGZO and IZO.
